(19) United States
(12) Patent Application Publication
(10) Pub. No.: US 2010/0062285 A1
(43) Pub. Date: Mar. 11, 2010

(54) MAGNETIC RECORDING MEDIUM AND METHOD OF MANUFACTURING THE SAME

(75) Inventor: Yasushi HATTORI, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM Corporation, Tokyo (JP)

(21) Appl. No.: 12/554,253

(22) Filed: Sep. 4, 2009

(30) Foreign Application Priority Data
Sep. 5, 2008 (JP) 2008-228164

(51) Int. Cl. G11B 5/62; G11B 5/84; C23C 14/34

(52) U.S. Cl. 428/800; 427/128; 204/192.15; G9B/5.289

(57) ABSTRACT

An aspect of the present invention relates to a magnetic recording medium comprising a magnetic layer on a nonmagnetic organic material support, wherein the magnetic layer comprises a magnetic material comprising a hard magnetic material comprising a rare earth element, and on a portion of a surface of the hard magnetic material, a soft magnetic region, and the soft magnetic region is exchange-coupled with the hard magnetic material. Another aspect of the present invention relates to a method of manufacturing a magnetic recording medium comprising forming a hard magnetic layer by coating a coating liquid comprising a hard magnetic material comprising a rare earth element on a nonmagnetic organic material support, and forming, on at least a portion of a surface of the hard magnetic material comprised in the hard magnetic layer, a soft magnetic region, the soft magnetic region being exchange-coupled with the hard magnetic material.

### CROSS-REFERENCE TO RELATED APPLICATIONS

This application claims the benefit of priority under 35 USC 119 to Japanese Patent Application No. 2008-228164, filed on Sep. 5, 2008, which is expressly incorporated herein by reference in its entirety.

### BACKGROUND OF THE INVENTION

1. Field of the Invention

The present invention relates to a magnetic recording medium and a method of manufacturing of the same.

2. Discussion of the Background

In widely employed magnetic recording media, such as video tapes, computer tapes, and disks, the smaller the particles of magnetic material, the higher the SNR becomes for a given content of magnetic material in the magnetic layer. This is advantageous for high-density recording.

However, as the size of the magnetic particles decreases, superparamagnetism ends up occurring due to thermal fluctuation, precluding use in a magnetic recording medium. By contrast, materials of high crystal magnetic anisotropy have good thermal stability due to a high potential for thermal stability. Accordingly, research has been conducted into materials of high crystal magnetic anisotropy as magnetic materials of good thermal stability. For example, high crystal magnetic anisotropy has been achieved by adding Pt to a CoCr-based magnetic material in hard disks (HD) and the like. Investigation has also been conducted into the use of CoPt, FePd, FePt, and the like as magnetic materials of higher crystal magnetic anisotropy. Further, magnetic materials containing rare earth elements, such as SmCo, NdFeB, and SmFeN, are known to be magnetic materials that do not contain expensive Pt, that are inexpensive, and that exhibit high crystal magnetic anisotropy (referred to as “Technique 1”, hereinafter).

Although materials of high crystal magnetic anisotropy afford good thermal stability, an increase in the switching magnetic field necessitates a large external magnetic field for recording, compromising recording properties. Accordingly, the Journal of the Magnetics Society of Japan 29, 239-242 (2005), which is expressly incorporated herein by reference in its entirety, describes attempts that have been made to reduce the switching magnetic field by stacking a soft magnetic layer and a hard magnetic layer formed as vapor phase films on a nonmagnetic inorganic material to produce exchange coupling interaction (referred to as “Technique 2”, hereinafter).

In metal thin-film magnetic recording media such as HD media, a glass substrate capable of withstanding high temperatures during vapor deposition is normally employed as the support. By contrast, particulate magnetic recording media affording good general-purpose properties and employing inexpensive organic material supports have been proposed in recent years, and are widely employed as video tapes, computer tapes, flexible disks, and the like. From the perspective of maintaining the general-purpose properties of such particulate media, it is difficult in practical terms to employ a magnetic material in which expensive Pt is used. Thus, the use of a magnetic material comprising a rare earth element such as in Technique 1 is conceivable. However, as set forth above, improvement of recording properties is required for magnetic materials of high crystal magnetic anisotropy.

Accordingly, the application of Technique 2 to magnetic recording media employing inexpensive organic material supports is conceivable to achieve both thermal stability and recording properties. However, in Technique 2, the support is exposed to high temperatures during vapor phase film formation. Thus, it is difficult to apply this technique to nonmagnetic organic material supports of poorer heat resistance than glass substrates.

### SUMMARY OF THE INVENTION

Accordingly, an aspect of the present invention provides for a magnetic recording medium with improved recording properties, that comprises a magnetic layer comprising a magnetic material of high crystal magnetic anisotropy on a nonmagnetic organic material support.

The present inventor conducted extensive research into achieving the above-stated magnetic recording medium, resulting in the discovery that by forming a soft magnetic region that is exchange-coupled with a hard magnetic material comprising a rare earth element on a portion of the hard magnetic material surface, it was possible to improve the recording properties of a magnetic material of high crystal magnetic anisotropy and good thermal stability. The present inventor further focused on the fact that while the sputtering temperature is extremely high with hard magnetic materials during vapor phase synthesis because the atoms must undergo rearrangement, the sputtering temperature is low with soft magnetic materials, permitting sputtering on organic material supports. As a result, he discovered that, not by synthesizing a hard magnetic material on an organic material support, but by coating a presynthesized hard magnetic material to form a hard magnetic layer, and then sputtering, or the like, a soft magnetic material thereover to form a soft magnetic region that was exchange-coupled with the hard magnetic material comprised in the hard magnetic layer on at least a portion of the hard magnetic material surface, it was possible to form a magnetic layer comprising a magnetic material that achieved both thermal stability and recording properties on a nonmagnetic organic material support.

The present invention was devised on that basis.

An aspect of the present invention relates to a magnetic recording medium comprising a magnetic layer on a nonmagnetic organic material support, wherein the magnetic layer comprises a magnetic material comprising a hard magnetic material comprising a rare earth element, and on at least a portion of a surface of the hard magnetic material, a soft magnetic region, and the soft magnetic region is exchange-coupled with the hard magnetic material.

The magnetic material may have an aspect ratio ranging from about 1.4 to about 5, preferably about 1.4 to about 3, and more preferably, about 1.2 to about 2.

The hard magnetic material may be comprised of a rare earth element, transition metal element, and boron.

A further aspect of the present invention relates to a method of manufacturing a magnetic recording medium comprising:

forming a hard magnetic layer by coating a coating liquid comprising a hard magnetic material comprising a rare earth element on a nonmagnetic organic material support, and

forming, on at least a portion of a surface of the hard magnetic material comprised in the hard magnetic layer, a soft magnetic region, the soft magnetic region being exchange-coupled with the hard magnetic material.

The formation of the soft magnetic region may be conducted by sputtering a soft magnetic material on the hard magnetic layer.

The hard magnetic material may be comprised of a rare earth element, transition metal element, and boron.

The present invention makes it possible to improve the recording properties of a magnetic recording medium comprising a magnetic layer containing a magnetic material of high crystal magnetic anisotropy.

Other exemplary embodiments and advantages of the present invention may be ascertained by reviewing the present disclosure.

### DETAILED DESCRIPTION OF THE EMBODIMENTS

Unless otherwise stated, a reference to a compound or component includes the compound or component by itself, as well as in combination with other compounds or components, such as mixtures of compounds.

As used herein, the singular forms “a,” “an,” and “the” include the plural reference unless the context clearly dictates otherwise.

Except where otherwise indicated, all numbers expressing quantities of ingredients, reaction conditions, and so forth used in the specification and claims are to be understood as being modified in all instances by the term “about.” Accordingly, unless indicated to the contrary, the numerical parameters set forth in the following specification and attached claims are approximations that may vary depending upon the desired properties sought to be obtained by the present invention. At the very least, and not to be considered as an attempt to limit the application of the doctrine of equivalents to the scope of the claims, each numerical parameter should be construed in light of the number of significant digits and ordinary rounding conventions.

Additionally, the recitation of numerical ranges within this specification is considered to be a disclosure of all numerical values and ranges within that range. For example, if a range is from about 1 to about 50, it is deemed to include, for example, 1, 7, 34, 46.1, 23.7, or any other value or range within the range.

The following preferred specific embodiments are, therefore, to be construed as merely illustrative, and non-limiting to the remainder of the disclosure in any way whatsoever. In this regard, no attempt is made to show structural details of the present invention in more detail than is necessary for fundamental understanding of the present invention; the description making apparent to those skilled in the art how several forms of the present invention may be embodied in practice.

### Magnetic Recording Medium

An aspect of the present invention relates to a magnetic recording medium comprising a magnetic layer on a nonmagnetic organic material support. The above magnetic layer comprises a magnetic material comprising a hard magnetic material comprising a rare earth element, and on a portion of a surface of the hard magnetic material, a soft magnetic region that is exchange-coupled with the hard magnetic material.

Hard magnetic materials comprising rare earth elements are excellent in thermal stability and exhibit high coercivity due to high crystal magnetic anisotropy. However, high coercivity necessitates a large external magnetic field for recording, compromising recording properties. In contrast, in the present invention, by forming a soft magnetic region that is exchange-coupled with the hard magnetic material on a portion of the hard magnetic material surface, it becomes possible to adjust the coercivity of the magnetic material to the level suitable for recording. Accordingly, the recording properties of magnetic materials with high crystal magnetic anisotropy can be improved.

In the present invention, the term “exchange coupling” refers to coupling of a hard magnetic material and a soft magnetic region such that the spin orientation is aligned by exchange interaction, the spin of the hard magnetic material and the spin of the soft magnetic region operate in concerted fashion, and the orientation of the spin changes as a single magnetic material. When a soft magnetic region is present on the surface of a hard magnetic material without undergoing exchange coupling, the coercivity of the hard magnetic material will not change depending on the presence or absence of the soft magnetic region. Accordingly, the fact that a hard magnetic material and a soft magnetic region have exchange-coupled can be confirmed based on whether or not the coercivity of the hard magnetic material is reduced by formation of the soft magnetic region. Further, when a soft magnetic region is present on the surface of a hard magnetic material without undergoing exchange coupling, the M-H loop (hysteresis loop) becomes the sum of the M-H loop of the soft magnetic material with the M-H loop of the hard magnetic material. Thus, in places corresponding to the coercivity of the soft magnetic material, segments appear in the M-H loop. Accordingly, exchange coupling of a hard magnetic material and a soft magnetic region can be confirmed from the shape of the M-H loop.

Further, in the present invention, the term “hard magnetic material” refers to a material having a coercivity of equal to or greater than 159 kA/m, and the term “soft magnetic material” or “soft magnetic region” refers to a material or region having a coercivity of less than 8 kA/m.

The above magnetic material will be described in greater detail below.

### Hard Magnetic Material

The hard magnetic material has good thermal stability due to high crystal magnetic anisotropy. The constant of crystal magnetic anisotropy of the hard magnetic material is desirably equal to or greater than about 6×10⁻¹ J/cc (about 6×10⁶ erg/cc). When the constant of crystal magnetic anisotropy is equal to or greater than about 6×10⁻¹ J/cc (about 6×10⁶ erg/cc), it is possible to maintain a coercivity suited to magnetic recording when exchange interaction with the soft magnetic material is imparted to the hard magnetic material to create exchange coupling. Additionally, when the constant of crystal magnetic anisotropy of the hard magnetic material exceeds about 6 J/cc (about 6×10⁷ erg/cc), coercivity will sometimes be high and recording properties poor even when it undergoes exchange coupling with the soft magnetic material. Thus, the constant of crystal magnetic anisotropy of the hard magnetic material is desirably equal to or lower than about 6 J/cc (about 6×10⁷ erg/cc).

From the perspective of recording properties, the saturation magnetization of the hard magnetic material is desirably about 5×10⁻¹ to about 2 A·m²/cc (about 500 emu/cc to about 2,000 emu/cc), preferably about 8×10⁻¹ to about 1.8 A·m²/cc (about 800 emu/cc to 1,800 emu/cc). It can be of any shape, such as spherical or polyhedral. From the perspective of high-density recording, the particle size (diameter) of the hard magnetic material is desirably about 3 to about 20 nm, preferably about 5 to about 10 nm. The “particle size” in the present invention can be measured by a transmission electron microscope (TEM). In the present invention, the average value of the particle size is the average value of the particle size measured by randomly extracting 500 particles in a photograph taken by a transmission electron microscope.

Magnetic materials comprised of rare earth elements, transition metal elements, and metalloids (also referred to hereinafter as “rare earth—transition metal—metalloid magnetic materials”) are known to be hard magnetic materials having suitable constants of crystal magnetic anisotropy.

Rare earth—transition metal—metalloid magnetic materials will be described in greater detail below.

### (Rare Earth—Transition Metal—Metalloid Magnetic Material)

Examples of rare earth elements are Y, Ce, Pr, Nd, Sm, Gd, Tb, Dy, Ho, Er, Tm, and Lu. Of these, Y, Ce, Pr, Nd, Gd, Tb, Dy, Ho, Pr, Nd, Tb, and Dy, which exhibit single-axis magnetic anisotropy, are preferred; Y, Ce, Gd, Ho, Nd, and Dy, which having constants of crystal magnetic anisotropy of about 6×10⁻¹ J/cc to about 6 J/cc (about 6×10⁶ erg/cc to about 6×10⁷ erg/cc), are of greater preference; and Y, Ce, Gd, and Nd are of even greater preference.

The transition metals Fe, Ni, and Co are desirably employed to form ferromagnetic materials. When employed singly, Fe, which has the greatest crystal magnetic anisotropy and saturation magnetization, is desirably employed.

Examples of metalloids are boron, carbon, phosphorus, silicon, and aluminum. Of these, boron and aluminum are desirably employed, with boron being optimal. That is, magnetic materials comprised of rare earth elements, transition metal elements, and boron (referred to as “rare earth—transition metal—boron magnetic materials”, hereinafter) are desirably employed as the above hard magnetic material. Rare earth—transition metal—metalloid magnetic materials including rare earth—transition metal—boron magnetic materials are advantageous from a cost perspective in that they do not contain expensive noble metals such as Pt, and can be suitably employed to fabricate magnetic recording media with good general-purpose properties.

The composition of the rare earth—transition metal—metalloid magnetic material is desirably about 10 atomic percent to about 15 atomic percent rare earth, about 70 atomic percent to about 85 atomic percent transition metal, and about 5 atomic percent to about 10 atomic percent metalloid.

When employing a combination of different transition metals as the transition metal, for example, the combination of Fe, Co, and Ni, denoted as Fe_{(1-x-y)} CoₓNi_{y}, desirably has a composition in the ranges of x=about 0 atomic percent to about 45 atomic percent and y=about 25 atomic percent to about 30 atomic percent; or the ranges of x=about 45 atomic percent to about 50 atomic percent and y=about 0 atomic percent to about 25 atomic percent, from the perspective of ease of controlling the coercivity of the hard magnetic material to the range of about 159 kA/m to about 638 kA/m (about 2,000 Oe to about 8,000 Oe).

From the perspective of low corrosion, the ranges of x=about 0 atomic percent to about 45 atomic percent and y=about 25 atomic percent to about 30 atomic percent, or the ranges of x=about 45 atomic percent to about 50 atomic percent and y=about 10 atomic percent to about 25 atomic percent, are desirable.

From the perspective of achieving good temperature characteristics with a Curie point of equal to or lower than about 500° C., the ranges of x=about 20 atomic percent to about 45 atomic percent and y=about 25 atomic percent to about 30 atomic percent, or the ranges of x=about 45 atomic percent to about 50 atomic percent and y=about 0 atomic percent to about 25 atomic percent, are desirable.

Accordingly, from the perspectives of coercivity, corrosion, and temperature characteristics, the ranges of x=about 20 atomic percent to about 45 atomic percent and y=about 25 atomic percent to about 30 atomic percent or the ranges of x=about 45 atomic percent to about 50 atomic percent and y=about 10 atomic percent to about 25 atomic percent are desirable, and the ranges of x=about 30 atomic percent to about 45 atomic percent and y=about 28 atomic percent to about 30 atomic percent are preferred.

The hard magnetic material can be synthesized by a vapor phase or liquid phase method, for example. However, the synthesis of a hard magnetic material of high crystal magnetic anisotropy requires a high temperature, and thus synthesis on a nonmagnetic organic material support is usually difficult in terms of the heat resistance of the support. Thus, it is desirable that the hard magnetic material is synthesized before coating it on a nonmagnetic organic material support.

One method of obtaining a rare earth—transition metal—boron magnetic material comprises melting the starting material metals in a high-frequency melting furnace and then conducting casting. In this method, since a product containing a large amount of transition metal as primary crystals is obtained, it is necessary to conduct solution heat treatment directly below the melting point to eliminate the transition metal. Since the particle size increases in solution heat treatment, it is desirable to employ the synthesis method set forth further below to obtain a microparticulate magnetic material suited to high-density recording.

In the quenching method in which molten metal is poured onto rotating rolls (molten metal quenching method), Fe in the form of primary crystals is not produced, making it possible to obtain microparticulate (desirably, with a particle size of about 3 nm to about 20 nm) rare earth—transition metal—boron nanocrystals in a thin quenched band.

Further, forming an amorphous alloy by the quenching method of pouring molten metal onto rotating rolls, followed by the method of conducting a heat treatment at about 400° C. to about 1,000° C. in a nonoxidizing atmosphere (such as an inert gas, nitrogen, or a vacuum) to precipitate nanocrystals can yield microparticulate (desirably, with a particle size of about 3 nm to about 20 nm) rare earth—transition metal—boron nanocrystals.

When employing a molten metal quenching method on an alloy, it is desirable to employ an inert gas atmosphere to prevent oxidation. Specific examples of inert gases that are desirably employed are He, Ar, and N₂.

In the molten metal quenching method, the quenching rate is determined based on the rotational speed of the rolls and the thickness of the thin quenched band. In the present invention, the rotational speed of the rolls in the course of forming rare earth—transition metal—boron nanocrystals in the thin quenched band immediately following quenching is desirably about 10 m/s to about 25 m/s. The rotational speed of about 25 m/s to about 50 m/s is desirable to obtain an amorphous alloy once following quenching.

The thickness of the thin quenched band is desirably about 10 μm to about 100 μm. It is desirable to control the quantity of molten metal that is poured by means of the orifice or the like to permit a thickness within the above range.

Subsequently, microparticles can be obtained using the method of microparticulating the particles in the course of adsorbing and desorbing hydrogen (the HDDR method), or by gas flow dispersion or wet dispersion.

A thin quenched band can be immersed in NaCl aqueous solution or Na₂SO₄ aqueous solution to dissolve and remove the rare earth—transition metal phase, thereby making it possible to obtain single crystals of rare earth—transition metal—metalloid. To avoid unanticipated oxidation, distilled water that has been deoxygenated is desirably employed when preparing the aqueous solution. Deoxygenated distilled water can be prepared by methods such as bubbling an inert gas such as Ar or N₂, or freezing and thawing distilled water.

The concentration of NaCl or Na₂SO₄ in the aqueous solution is desirably about 0.01 kmol/m³ to about 1 kmol/m³, preferably about 0.05 kmol/m³ to about 0.5 kmol/m³.

### Soft Magnetic Region

The soft magnetic region (also referred to as the “soft magnetic material”, hereinafter) formed on the surface of the above hard magnetic material will be described next.

From the perspectives of achieving exchange coupling with the hard magnetic material to control the coercivity of the magnetic material to a level suited to magnetic recording, the constant of crystal magnetic anisotropy of the soft magnetic material is desirably as low as possible, and a material with a negative value can be selected. However, when a soft magnetic material having a negative constant of crystal magnetic anisotropy is caused to exchange couple with a hard magnetic material, the magnetic energy of the magnetic material decreases. Thus, the constant of crystal magnetic anisotropy of the soft magnetic material is desirably about 0 J/cc to about 5×10⁻² J/cc (about 0 erg/cc to about 5×10⁵ erg/cc), preferably about 0 J/cc to about 1×10⁻² J/cc (about 0 erg/cc to about 1×10⁵ erg/cc).

The saturation magnetization of the soft magnetic material is desirably as high as possible from the perspectives of achieving exchange coupling with the hard magnetic material to control the coercivity of the magnetic material to a level suited to magnetic recording. Specifically, a range of about 1×10⁻¹ A·m²/cc to about 2 A·m²/cc (about 100 emu/cc to about 2,000 emu/cc) is desirable, and a range of about 3×10⁻¹ A·m²/cc to about 1.8 A·m²/cc (about 300 emu/cc to about 1,800 emu/cc) is preferred.

Fe, Fe alloys, and Fe compounds, such as iron, permalloy, sendust, and soft ferrite, are desirably employed as the soft magnetic material.

### Hard and Soft Magnetic Materials

From the perspective of controlling the coercivity of the magnetic material during coupling to a level suited to magnetic recording, the exchange coupling energy between the hard magnetic material and the soft magnetic material is desirably adjusted to a suitable value in accordance with the constant of crystal magnetic anisotropy of the hard magnetic material. Specifically, a soft magnetic material having a constant of crystal magnetic anisotropy of about 0.1-fold to about 0.3-fold that of the hard magnetic material is desirably employed.

The exchange coupling energy can be adjusted by means of boundary impurities, distortion, crystalline structure, and the like.

In the magnetic recording medium of the present invention, the magnetic material comprised in the magnetic layer comprises a soft magnetic region exchange-coupled with the hard magnetic material comprising a rare earth element, on a portion of the surface of the hard magnetic material. From the perspective of controlling the coercivity of the magnetic material to a level suited to magnetic recording, the volumetric ratio of the hard magnetic material and the soft magnetic region in the magnetic material is desirably such that the volume of the soft magnetic region is equal to or greater than the volume of the hard magnetic material. The volumetric ratio of the two (hard magnetic material/soft magnetic region) is preferably from about 1/1 to about 1/20, and more preferably, from about 1/5 to about 1/15.

The aspect ratio of the magnetic material following formation of the soft magnetic region is desirably about 1.4 to about 5, preferably about 1.4 to about 3, and more preferably, about 1.2 to about 2.

In the present invention, the aspect ratio is defined as the ratio of the length of the magnetic material in the magnetic layer in a direction perpendicular to the support to its length in the direction of the support, and is calculated as the average of the values measured for 500 particles randomly extracted from a photograph taken by a transmission electron microscope.

A magnetic material with a high aspect ratio for a given volume will have a smaller projected area on the support than a magnetic material with low aspect ratio. This is advantageous in terms of electromagnetic characteristics in that it increases the number of particles per recording bit. Acicular magnetic material has come to be employed in conventional particulate magnetic recording media. Due to in-plane recording, in acicular magnetic materials, the axis of easy magnetization (major axis direction) or plate diameter direction tends to be oriented horizontally relative to the support by fluid orientation, making it difficult to achieve an aspect ratio falling within the above range. By contrast, in the present invention, it is possible to obtain a magnetic material having an aspect ratio within the above range in a magnetic layer by causing the soft magnetic material to exchange couple with the hard magnetic material. From the perspective of obtaining a magnetic material having an aspect ratio falling within the above range, it is desirable for the ratio of the long side/short side of the hard magnetic material to be about 0.7 to about 1.5 prior to forming the soft magnetic region.

The magnetic recording medium of the present invention is desirably manufactured by the method of coating a coating liquid that has been prepared by suitably mixing hard magnetic particles with binder, additives, a polar solvent, and a nonpolar solvent, on a nonmagnetic organic material support to form a hard magnetic layer, and subsequently exchange coupling a soft magnetic material with the hard magnetic layer. Crystal magnetic anisotropy depends on a crystalline structure. Therefore, when sputtering a hard magnetic material of high crystal magnetic anisotropy, a high sputtering temperature becomes high because it is necessary to induce rearrangement of the atoms. Thus, the sputtering of a hard magnetic material on a nonmagnetic organic material support is difficult from the perspective of the heat resistance of the nonmagnetic organic material support. Accordingly, it is desirable for the magnetic recording medium of the present invention that a coating liquid comprising presynthesized hard magnetic particles is coated on a nonmagnetic organic material support to form a hard magnetic layer, after which a soft magnetic material is exchange-coupled with the hard magnetic material comprised in the hard magnetic layer.

A liquid phase method or a vapor phase method may be employed to exchange-couple the soft magnetic material. A vapor phase method in the form of the method of sputtering a soft magnetic material on the hard magnetic layer is desirably employed. As set forth above, the sputtering temperature of the hard magnetic material is high. By contrast, since the magnetic anisotropy of the soft magnetic material is low and thus there is no need to induce rearrangement of the atoms, the sputtering temperature can be low for the soft magnetic material. Accordingly, a soft magnetic material can be sputtered on an organic material support. The substrate temperature in sputtering of a soft magnetic material is, for example, about 30° C. to about 250° C., desirably about 30° C. to about 10° C. A known sputtering device may be employed.

To cause the soft magnetic material to exchange-couple with the hard magnetic material, it is desirable to remove organic material that has adsorbed to the hard magnetic particles by milling or the like prior to preparing the hard magnetic layer coating liquid. This is because direct coupling of the hard magnetic material to the soft magnetic material is required for exchange coupling. The binder and additives in the hard magnetic layer may impede exchange coupling. Thus, prior to exchange coupling the soft magnetic material, it is desirable to conduct ion etching or the like to remove such components that are present on the surface of the hard magnetic layer.

### Nonmagnetic Organic Material Support

Various nonmagnetic supports made of organic material can be employed without limitation as a support in the present invention. Flexible supports are desirable.

Known films of the following may be employed as the flexible nonmagnetic organic material support: polyethylene terephthalate, polyethylene naphthalate, other polyesters, polyolefins, cellulose triacetate, polycarbonate, aromatic polyamides, aliphatic polyamides, polyimides, polyamidoimides, polysulfones, polybenzooxazoles, and the like. Of these, the use of polyethylene naphthalate, polyamide, or some other high-strength support is desirable.

As needed, layered supports such as disclosed in Japanese Unexamined Patent Publication (KOKAI) Heisei No. 3-224127, which is expressly incorporated herein by reference in its entirety, may be employed to vary the surface roughness of the support surface on which a magnetic layer is coated and that of the support surface on which a back layer is coated. These supports may be subjected beforehand to corona discharge treatment, plasma treatment, adhesion enhancing treatment, heat treatment, dust removal, and the like.

Normally, the center surface average surface roughness (Ra) of the support as measured with an optical interferotype surface roughness meter HD-2000 made by WYKO is preferably equal to or less than about 8.0 nm, more preferably equal to or less than about 4.0 nm, further preferably equal to or less than about 2.0 nm. Not only does such a support desirably have a low center surface average surface roughness (Ra), but there are also desirably no large protrusions equal to or higher than about 0.5 μm.

The surface roughness shape may be freely controlled through the size and quantity of filler added to the support as needed. Examples of such fillers are inorganic microparticles of oxides and carbonates of elements such as Ca, Si, and Ti, and organic micropowders such as acrylic-based one. The support desirably has a maximum height Rₘₐₓ equal to or less than about 1 μm, a ten-point average roughness R_{Z} equal to or less than about 0.5 μm, a center surface peak height R_{P} equal to or less than about 0.5 μm, a center surface valley depth R_{V} equal to or less than about 0.5 μm, a center-surface surface area percentage Sr of about 10 percent to about 90 percent, and an average wavelength λ a of about 5 μm to about 300 μm. To achieve desired electromagnetic characteristics and durability, the surface protrusion distribution of the support can be freely controlled with fillers. It is possible to control within a range from about 0 to about 2,000 protrusions of 0.01 to 1 μm in size per 0.1 mm².

The F-5 value of the support desirably ranges from about 5 kg/mm² to about 50 kg/mm² (about 49 MPa to about 490 MPa). The thermal shrinkage rate of the support after 30 min at 100° C. is preferably equal to or less than about 3 percent, more preferably equal to or less than about 1.5 percent. The thermal shrinkage rate after 30 min at 80° C. is preferably equal to or less than about 1 percent, more preferably equal to or less than about 0.5 percent. The breaking strength of the support preferably ranges from about 5 kg/mm² to about 100 kg/mm² (about 49 MPa to about 980 MPa). The modulus of elasticity preferably ranges from about 100 kg/mm² to about 2,000 kg/mm² (about 0.98 GPa to about 19.6 GPa). The thermal expansion coefficient preferably ranges from about 10⁻⁴/° C. to about 10⁻⁸/° C., more preferably from about 10⁻⁵/° C. to about 10⁻⁶/° C. The moisture expansion coefficient is preferably equal to or less than about 10⁻⁴/RH percent, more preferably equal to or less than about 10⁻⁵/RH percent. These thermal characteristics, dimensional characteristics, and mechanical strength characteristics are desirably nearly equal, with a difference equal to less than about 10 percent, in all in-plane directions in the support.

The thickness of the support desirably ranges from about 2 μm to about 100 μm, preferably from about 2 μm to about 80 μm. For computer-use tapes, the support having a thickness of about 3.0 μm to about 6.5 μm, preferably about 3.0 μm to about 6.0 μm, more preferably about 4.0 μm to about 5.5 μm is suitably employed.

### Magnetic Layer

In addition to the above-described magnetic material, the magnetic layer can optionally contain binder, various additives, and the like.

In the magnetic recording medium of the present invention, the above-described magnetic layer may be provided on one or both sides of the support. From the perspectives of lubricant supply sources and covering protrusions on the support, a nonmagnetic layer can be provided between the support and the magnetic layer.

When forming a nonmagnetic layer on the support, the magnetic layer (also referred to as the “upper layer” or “upper magnetic layer”) can be provided while the nonmagnetic layer is still wet (W/W) once the nonmagnetic layer has been coated, or can be provided after the nonmagnetic layer has dried (W/D). Simultaneous or successive wet coatings are desirable from the perspective of production yield ratio, but coating after drying can be adequately employed in the case of disks.

In simultaneous or successive wet coating (W/W), since the nonmagnetic layer and magnetic layer can be simultaneously formed, a surface processing step such as calendering can be effectively utilized to improve the surface roughness of the upper magnetic layer, even when the upper layer is ultrathin.

The magnetic layer is desirably about 0.005 μm to about 0.20 μm, preferably about 0.05 μm to about 0.15 μm, in thickness. The magnetic layer with a thickness of about 0.005 μm to about 0.20 μm can prevent a drop in reproduction output and the deterioration of overwrite characteristics and resolution.

Further, the embodiment of a single particle layer coating of hard magnetic particles is desirable from the perspective of exchange coupling the soft magnetic material with the hard magnetic particles after coating the hard magnetic layer. As set forth above, when incorporating binder and various additives into the hard magnetic layer, it is desirable to conduct ion etching or the like to remove such components from the surface of the hard magnetic layer.

### Carbon Black and Abrasives

Carbon black can be incorporated into the magnetic layer. Carbon black may be employed in the form of furnace black for rubber, thermal for rubber, black for coloring, acetylene black, and the like.

The specific surface area (S_{BET}) of the carbon black by the BET method is desirably about 5 m²/g to about 500 m²/g, and the DBP oil absorption capacity is desirably about 10 mL/100 g to about 400 mL/100 g. The average particle diameter is desirably about 5 nm to about 300 nm, preferably about 10 nm to about 250 nm, and more preferably, about 20 nm to about 200 nm. The pH is desirably about 2 to about 10. The moisture content is desirably about 0.1 percent to about 10 percent. And the tap density is desirably about 0.1 g/mL to about 1 g/mL.

Specific examples of types of carbon black employed are: BLACK PEARLS 2000, 1300, 1000, 900, 905, 800, 700 and VULCAN XC-72 from Cabot Corporation; #80, #60, #55, #50 and #35 manufactured by Asahi Carbon Co., Ltd.; #2400B, #2300, #900, #1000, #30, #40 and #10B from Mitsubishi Chemical Corporation; CONDUCTEX SC, RAVEN 150, 50, 40, 15 and RAVEN-MT-P from Columbia Carbon Co., Ltd.; and Ketjen Black EC from Lion Akzo Co., Ltd.

The carbon black employed may be surface-treated with a dispersant or grafted with resin, or have a partially graphite-treated surface. The carbon black may be dispersed in advance into the binder prior to addition to the magnetic layer coating liquid. These carbon black may be used singly or in combination. The quantity of carbon black preferably ranges from about 0.1 weight percent to about 30 weight percent relative to the total weight of the magnetic material (magnetic particle), when carbon black is employed. In the magnetic layer, carbon black can work to prevent static, reduce the coefficient of friction, impart light-blocking properties, enhance film strength, and the like; the properties vary with the type of carbon black employed. Accordingly, carbon blacks with different types, different quantities and different combination can be employed in the upper magnetic layer and lower nonmagnetic layer in light of various characteristics such as particle size, oil absorption capacity, electrical conductivity, and pH. The carbon black is preferably optimized for each layer. For example, Carbon Black Handbook compiled by the Carbon Black Association, which is expressly incorporated herein by reference in its entirety, may be consulted for types of carbon black suitable for use in the magnetic layer and/or nonmagnetic layer.

The magnetic layer may comprise abrasives. Known materials chiefly having a Mohs' hardness of equal to or greater than about 6 may be employed either singly or in combination as abrasives. These include: α-alumina with an α-conversion rate of equal to or greater than about 90 percent, β-alumina, silicon carbide, chromium oxide, cerium oxide, α-iron oxide, corundum, synthetic diamond, silicon nitride, silicon carbide, titanium carbide, titanium oxide, silicon dioxide, and boron nitride. Complexes of these abrasives (obtained by surface treating one abrasive with another) may also be employed. There are cases in which compounds or elements other than the primary compound are contained in these abrasives; the effect does not change so long as the content of the primary compound is equal to or greater than about 90 weight percent.

The average particle size of the abrasive is preferably about 0.01 μm to about 2 μm, more preferably about 0.05 μm to about 1.0 μm, and further preferably, about 0.05 μm to about 0.5 μm. To enhance electromagnetic characteristics, a narrow particle size distribution is desirable. Abrasives of differing particle size may be incorporated as needed to improve durability; the same effect can be achieved with a single abrasive with a wide particle size distribution. It is preferable that the tap density of the abrasive is about 0.3 g/cc to about 2 g/cc, the moisture content is about 0.1 percent to about 5 percent, the pH is about 2 to about 11, and the specific surface area, S_{BET}, is about 1 m²/g to about 30 m²/g. The shape of the abrasive may be acicular, spherical, cubic, or the like. However, a shape comprising an angular portion is desirable due to high abrasiveness.

Specific examples of additives are AKP-12, AKP-15, AKP-20, AKP-30, AKP-50, HIT-20, HIT-30, HIT-55, HIT-60A, HIT-70, HIT-80, and HIT-100 made by Sumitomo Chemical Co., Ltd.; ERC-DBM, HP-DBM, and HPS-DBM made by Reynolds Corp.; WA10000 made by Fujimi Abrasive Corp.; UB20 made by Uemura Kogyo Corp.; G-5, Chromex U2, and Chromex U1 made by Nippon Chemical Industrial Co., Ltd.; TF100 and TF140 made by Toda Kogyo Corp.; Beta Random Ultrafine made by Ibiden Co., Ltd.; and B-3 made by Showa Kogyo Co., Ltd. Abrasives may be added as needed to the nonmagnetic layer. Addition of abrasives to the nonmagnetic layer can be done to control surface shape, control how the abrasive protrudes, and the like. The particle diameter and quantity of the abrasives added to the magnetic layer and nonmagnetic layer are preferably set to optimal values.

### Other Additives

In addition to carbon black and abrasives described above, various additives may be incorporated into the magnetic layer and the nonmagnetic layer described further below. For example, substances having lubricating effects, antistatic effects, dispersive effects, plasticizing effects, or the like may be employed as additives in the magnetic layer and nonmagnetic layer.

Examples of additives are: molybdenum disulfide; tungsten disulfide; graphite; boron nitride; graphite fluoride; silicone oils; silicones having a polar group; fatty acid-modified silicones; fluorine-containing silicones; fluorine-containing alcohols; fluorine-containing esters; polyolefins; polyglycols; alkylphosphoric esters and their alkali metal salts; alkylsulfuric esters and their alkali metal salts; polyphenyl ethers; phenylphosphonic acid; α-naphthylphosphoric acid; phenylphosphoric acid; diphenylphosphoric acid; p-ethylbenzenephosphonic acid; phenylphosphinic acid; aminoquinones; various silane coupling agents and titanium coupling agents; fluorine-containing alkylsulfuric acid esters and their alkali metal salts; monobasic fatty acids (which may contain an unsaturated bond or be branched) having 10 to 24 carbon atoms and metal salts (such as Li, Na, K, and Cu) thereof, monohydric, dihydric, trihydric, tetrahydric, pentahydric or hexahydric alcohols with 12 to 22 carbon atoms (which may contain an unsaturated bond or be branched); alkoxy alcohols with 12 to 22 carbon atoms; monofatty esters, difatty esters, or trifatty esters comprising a monobasic fatty acid having 10 to 24 carbon atoms (which may contain an unsaturated bond or be branched) and any one from among a monohydric, dihydric, trihydric, tetrahydric, pentahydric or hexahydric alcohol having 2 to 12 carbon atoms (which may contain an unsaturated bond or be branched); fatty acid esters of monoalkyl ethers of alkylene oxide polymers; fatty acid amides with 8 to 22 carbon atoms; and aliphatic amines with 8 to 22 carbon atoms.

Specific examples of the additives in the form of fatty acids are: capric acid, caprylic acid, lauric acid, myristic acid, palmitic acid, stearic acid, behenic acid, oleic acid, elaidic acid, linolic acid, linolenic acid, and isostearic acid. Examples of esters are butyl stearate, octyl stearate, amyl stearate, isooctyl stearate, butyl myristate, octyl myristate, butoxyethyl stearate, butoxydiethyl stearate, 2-ethylhexyl stearate, 2-octyldodecyl palmitate, 2-hexyldodecyl palmitate, isohexadecyl stearate, oleyl oleate, dodecyl stearate, tridecyl stearate, oleyl erucate, neopentylglycol didecanoate, and ethylene glycol dioleyl. Examples of alcohols are oleyl alcohol, stearyl alcohol, and lauryl alcohol.

It is also possible to employ nonionic surfactants such as alkylene oxide-based surfactants, glycerin-based surfactants, glycidol-based surfactants and alkylphenolethylene oxide adducts; cationic surfactants such as cyclic amines, ester amides, quaternary ammonium salts, hydantoin derivatives, heterocycles, phosphoniums, and sulfoniums; anionic surfactants comprising acid groups, such as carboxylic acid, sulfonic acid, phosphoric acid, sulfuric ester groups, and phosphoric ester groups; and ampholytic surfactants such as amino acids, amino sulfonic acids, sulfuric or phosphoric esters of amino alcohols, and alkyl betaines. Details of these surfactants are described in A Guide to Surfactants (published by Sangyo Tosho K.K.), which is expressly incorporated herein by reference in its entirety. These lubricants, antistatic agents and the like need not be 100 percent pure and may contain impurities, such as isomers, unreacted material, by-products, decomposition products, and oxides in addition to the main components. These impurities are preferably comprised equal to or less than about 30 weight percent, and more preferably equal to or less than about 10 weight percent.

Each of the lubricants and surfactants has different physical effects. The type, quantity, and combination ratio of lubricants or surfactants producing synergistic effects can be optimally set for a given objective. It is conceivable to control bleeding onto the surface through the use of fatty acids having different melting points in the nonmagnetic layer and the magnetic layer; to control bleeding onto the surface through the use of esters having different boiling points, melting points, and polarity; to improve the stability of coatings by adjusting the quantity of surfactant; and to increase the lubricating effect by increasing the amount of lubricant in the intermediate layer. The present invention is not limited to these examples. In general, the total amount of lubricant is preferably about 0.1 weight percent to about 50 weight percent, and more preferably about 2 weight percent to about 25 weight percent with respect to the magnetic material (magnetic particle) or nonmagnetic powder.

Conventionally known thermoplastic resins, thermosetting resins, reactive resins, and mixtures of the same, that are usually employed as binder of magnetic recording media, can be employed without any limitation, as the binder suitable for use in the magnetic layer. These binders may be employed in the nonmagnetic layer. The quantity of binder employed in the magnetic layer and the nonmagnetic layer ranges from, for example, about 5 weight percent to about 50 weight percent, preferably from about 10 weight percent to about 30 weight percent, relative to the nonmagnetic powder or magnetic material.

All or a portion of the additives employed in the present invention can be added during any step in the manufacturing of a magnetic layer coating liquid and nonmagnetic layer coating liquid. For example, there are times when they are mixed with the magnetic material before the kneading step, times when they are added with the magnetic material, binder and solvent in the kneading step, times when they are added during the dispersing step, times when they are added after the dispersing step, and times when they are added immediately prior to coating.

Based on the objective, there are times when an objective is achieved by coating all or part of the additives in simultaneous or successive coatings after coating the magnetic layer. Based on the objective, there are times when a lubricant is coated to the magnetic layer surface after calendering or slitting has been completed.

### Nonmagnetic Layer

In the magnetic recording medium of the present invention, a magnetic layer comprising the above-described magnetic material is present on a nonmagnetic organic material support. As necessary, a nonmagnetic layer can be provided between the magnetic layer and the support. A structure comprising a suitable back layer, undercoating layer, protective layer, or the like can also be adopted.

The structure of the nonmagnetic layer need not be limited so long as it is essentially nonmagnetic. It normally comprises at least a resin and desirably comprises powder; an example is an inorganic or organic powder dispersed in a resin. The inorganic or organic powder is desirably a nonmagnetic powder, but a magnetic powder may be employed to the extent that the nonmagnetic layer remains essentially nonmagnetic.

The particle size (particle diameter) of these nonmagnetic powders preferably ranges from about 0.005 μm to about 2 μm, but nonmagnetic powders of differing particle size may be combined as needed, or the particle diameter distribution of a single nonmagnetic powder may be broadened to achieve the same effect. What is preferred most is a particle diameter in the nonmagnetic powder ranging from about 0.01 μm to about 0.2 μm. Particularly when the nonmagnetic powder is a granular metal oxide, an average particle diameter equal to or less than about 0.08 μm is preferred, and when an acicular metal oxide, the major axis length is preferably equal to or less than about 0.3 μm, more preferably equal to or less than about 0.2 μm. The tap density preferably ranges from about 0.05 g/ml to about 2 g/ml, more preferably from about 0.2 g/ml to about 1.5 g/ml. The moisture content of the nonmagnetic powder preferably ranges from about 0.1 weight percent to about 5 weight percent, more preferably from about 0.2 weight percent to about 3 weight percent, further preferably from about 0.3 weight percent to about 1.5 weight percent. The pH of the nonmagnetic powder preferably ranges from about 2 to about 11, and the pH between about 5.5 to about 10 is particular preferred.

The specific surface area, S_{BET}, of the nonmagnetic powder preferably ranges from about 1 m²/g to about 100 m²/g, more preferably from about 5 m²/g to about 80 m²/g, further preferably from about 10 m²/g to about 70 m²/g. The crystallite size (crystallite diameter) of the nonmagnetic powder preferably ranges from about 0.004 μm to about 1 μm, further preferably from about 0.04 μm to about 0.1 μm. The oil absorption capacity using dibutyl phthalate (DBP) preferably ranges from about 5 ml/100 g to about 100 ml/100 g, more preferably from about 10 ml/100 g to about 80 ml/100 g, further preferably from about 20 ml/100 g to about 60 ml/100 g. The specific gravity of the nonmagnetic powder preferably ranges from about 1 to about 12, more preferably from about 3 to about 6. The shape of the nonmagnetic powder may be any of acicular, spherical, polyhedral, or plate-shaped. The nonmagnetic powder having a Mohs' hardness ranging from about 4 to about 10 is preferred. The stearic acid (SA) adsorption capacity of the nonmagnetic powder preferably ranges from about 1 μmol/m² to about 20 μmol/m², more preferably from about 2 μmol/m² to about 15 μmol/m², further preferably from about 3 μmol/m² to about 8 μmol/m². The pH of the nonmagnetic powder preferably ranges from about 3 to about 6.

The nonmagnetic powder can be selected from inorganic compounds such as metal oxides, metal carbonates, metal sulfates, metal nitrides, metal carbides, metal sulfides and the like. Examples of inorganic compounds are α-alumina having an α-conversion rate of about 90 percent to about 100 percent, β-alumina, γ-alumina, θ-alumina, silicon carbide, chromium oxide, cerium oxide, α-iron oxide, hematite, goethite, corundum, silicon nitride, titanium carbide, titanium dioxide, silicon dioxide, tin oxide, magnesium oxide, tungsten oxide, zirconium oxide, boron nitride, zinc oxide, calcium carbonate, calcium sulfate, barium sulfate and molybdenum disulfide; these may be employed singly or in combination. Particularly desirable are titanium dioxide, zinc oxide, iron oxide and barium sulfate due to their narrow particle distribution and numerous means of imparting functions. Even more preferred is titanium dioxide and α-iron oxide.

Specific examples (product names) of nonmagnetic powders are: Nanotite from Showa Denko K. K.; HIT-100 and ZA-G1 from Sumitomo Chemical Co., Ltd.; α-hematite DPN-250, DPN-250BX, DPN-245, DPN-270BX, DPN-500BX, DBN-SA1 and DBN-SA3 from Toda Kogyo Corp.; titanium oxide TTO-51B, TTO-55A, TTO-55B, TTO-55C, TTO-55S, TTO-55D, SN-100, α-hematite E270, E271, E300 and E303 from Ishihara Sangyo Co., Ltd.; titanium oxide STT-4D, STT-30D, STT-30, STT-65C, and α-hematite α-40 from Titan Kogyo K. K.; MT-100S, MT-100T, MT-150W, MT-500B, MT-600B, MT-100F, and MT-500HD from Tayca Corporation; FINEX-25, BF-1, BF-10, BF-20, and ST-M from Sakai Chemical Industry Co., Ltd.; DEFIC-Y and DEFIC-R from Dowa Mining Co., Ltd.; AS2BM and TiO₂P25 from Nippon Aerogil; and 100A and 500A from Ube Industries, Ltd.

The surface of these nonmagnetic powders is preferably treated with Al₂O₃, SiO₂, TiO₂, ZrO₂, SnO₂, Sb₂O₃, ZnO and Y₂O₃. The surface-treating agents of preference with regard to dispersibility are Al₂O₃, SiO₂, TiO₂ and ZrO₂, and Al₂O₃, SiO₂ and ZrO₂ are further preferable. These may be used singly or in combination. Depending on the objective, a surface-treatment coating layer with a coprecipitated material may also be employed, the coating structure which comprises a first alumina coating and a second silica coating thereover or the reverse structure thereof may also be adopted. Depending on the objective, the surface-treatment coating layer may be a porous layer, with homogeneity and density being generally desirable.

Carbon black can be mixed into the nonmagnetic layer to achieve the known effect of reducing surface resistivity Rs and optical transmittance, and achieving a desired micro-Vicker's hardness. A lubricant stockpiling effect can also be achieved by incorporating carbon black into the nonmagnetic layer. For example, furnace black for rubber, thermal for rubber, black for coloring and acetylene black can be employed. Based on the desired effects, different types of carbon black can be employed in combination in the nonmagnetic layer in light of various characteristics as described below.

The specific surface area, S_{BET}, of the carbon black employed in the nonmagnetic layer is preferably about 100 m²/g to about 500 m²/g, more preferably about 150 m²/g to about 400 m²/g. The DBP oil absorption capability is preferably about 20 mL/100 g to about 400 mL/100 g, more preferably about 30 mL/100 g to about 400 mL/100 g. The particle diameter of the carbon black is preferably about 5 nm to about 80 nm, more preferably about 10 nm to about 50 nm, and further preferably, about 10 nm to about 40 nm. It is preferable that the pH of the carbon black is about 2 to about 10, the moisture content is about 0.1 percent to about 10 percent, and the tap density is about 0.1 g/mL to about 1 g/mL.

Specific examples (product names) of types of carbon black employed in the nonmagnetic layer are: BLACK PEARLS 2000, 1300, 1000, 900, 800, 880, 700 and VULCAN XC-72 from Cabot Corporation; #3050B, #3150B, #3250B, #3750B, #3950B, #950, #650B, #970B, #850B, MA-600, MA-230, #4000 and #4010 from Mitsubishi Chemical Corporation; CONDUCTEX SC, RAVEN 8800, 8000, 7000, 5750, 5250, 3500, 2100, 2000, 1800, 1500, 1255 and 1250 from Columbia Carbon Co., Ltd.; and Ketjen Black EC from Lion Akzo Co., Ltd.

The carbon black employed may be surface-treated with a dispersant or grafted with resin, or have a partially graphite-treated surface. The carbon black may be dispersed in advance into the binder prior to addition to the coating liquid. The quantity of the carbon black is preferably within a range not exceeding about 50 weight percent of the inorganic powder as well as not exceeding about 40 percent of the total weight of the nonmagnetic layer. These carbon blacks may be used singly or in combination. For example, the Carbon Black Handbook compiled by the Carbon Black Association may be consulted for types of carbon black suitable for use in the present invention.

Based on the objective, an organic powder may be added to the nonmagnetic layer. Examples of such an organic powder are acrylic styrene resin powders, benzoguanamine resin powders, melamine resin powders, and phthalocyanine pigments. Polyolefin resin powders, polyester resin powders, polyamide resin powders, polyimide resin powders, and polyfluoroethylene resins may also be employed. The manufacturing methods described in Japanese Unexamined Patent Publication (KOKAI) Showa Nos. 62-18564 and 60-255827 may be employed. The contents of the above publications are expressly incorporated herein by reference in their entirety.

The thickness of the nonmagnetic layer preferably ranges from about 0.2 μm to about 5.0 μm, more preferably about 0.3 μm to about 3.0 μm, and further preferably, about 1.0 μm to about 2.5 μm.

The nonmagnetic layer is effective so long as it is substantially nonmagnetic. For example, it may comprise impurities or trace amounts of magnetic material that have been intentionally incorporated. The term “substantially nonmagnetic” is used to mean having a residual magnetic flux density in the nonmagnetic layer of equal to or less than about 10 mT, or a coercivity of equal to or less than about 7.96 kA/m (about 100 Oe), it being preferable not to have a residual magnetic flux density or coercivity at all.

Known techniques regarding binder resins, lubricants, dispersion agents, additives, solvents, dispersion methods and the like for magnetic layer can be suitably applied to the nonmagnetic layer. In particular, known techniques regarding the quantity and types of binders, additives and dispersion agents for magnetic layer can be applied.

An undercoating layer may be provided between the support and the nonmagnetic layer or magnetic layer to enhance adhesion. The undercoating layer is desirably about 0.01 μm to about 0.5 μm, preferably about 0.02 μm to about 0.5 μm, in thickness. The magnetic recording medium of the present invention can be a disk medium in which a nonmagnetic layer and a magnetic layer are provided on both surfaces of a support, or a tape medium or disk medium in which they are provided on just one surface. In that case, a back layer can be provided on the opposite side from the nonmagnetic layer and magnetic layer to achieve effects such as preventing static and correcting for curling. The thickness of the back layer is desirably about 0.1 μm to about 4 μm, preferably about 0.3 μm to about 2.0 μm. Known materials may be employed in the undercoating layer and back layer, described further below.

### Back Layer

Generally, a magnetic tape for recording computer data is required to have better repeat running properties than a video tape or audio tape. To maintain such high running durability, carbon black and inorganic powder are desirably incorporated into the back layer.

Two types of carbon black having different average particle diameters are desirably employed in combination. In that case, microparticulate carbon black having an average particle diameter of about 10 nm to about 20 nm and coarse particulate carbon black having an average particle diameter of about 230 nm to about 300 nm are desirably combined for use.

Generally, the surface resistivity and light transmittance of the back layer can be set low by adding microparticulate carbon black such as that set forth above. In many magnetic recording devices, the light transmittance of the tape is used as an operating signal. Thus, in such cases, the addition of microparticulate carbon black is particularly effective. Microparticulate carbon black generally affords good liquid lubricant retentivity, and contributes to reducing the coefficient of friction when employed in combination with a lubricant.

The coarse particulate carbon black with an average particle diameter of about 230 nm to about 300 nm can function as a solid lubricant and form microprotrusions on the surface of the back layer to reduce the contact area, thereby contributing to reducing the coefficient of friction. However, when coarse particulate carbon black is employed alone, it may present a drawback in that tape sliding in severe running systems tends to cause it to drop out of the back layer, increasing the error ratio. Thus, it is desirably employed in combination with microparticulate carbon black.

The following are examples of specific microparticulate carbon black products. The numbers in parentheses are average volumetric particle diameters: RAVEN 200B (18 nm), RAVEN 1500B (17 nm) (the above are made by Columbia Carbon Co., Ltd.); BP800 (17 nm) (made by Cabot Corp.); PRINTEX 90 (14 nm), PRINTEX 95 (15 nm), PRINTEX 85 (16 nm), PRINTEX 75 (17 nm) (made by Degusa Corp.); and #3950 (16 nm) (made by Mitsubishi Chemical Corporation).

The following are examples of specific coarse particulate carbon black products: Thermal Black (270 nm) (made by Cancarb, Ltd.); RAVEN MTP (275 nm) (made by Columbia Carbon Co., Ltd.).

When employing two types having different average particle diameters in the back layer, the content ratio (weight ratio) of microparticulate carbon black having an average particle diameter of about 10 nm to about 20 nm to coarse particulate carbon black of about 230 nm to about 300 nm desirably falls within a former:latter range of about 98:2 to about 75:25, preferably a range of about 95:5 to about 85:15.

The content of carbon black (the total quantity when two types are employed) in the back layer normally falls within a range of about 30 weight parts to about 80 weight parts, desirably a range of about 45 weight parts to about 65 weight parts, per 100 weight parts of binder.

Two types of inorganic powder of differing hardness are desirably employed in combination. Specifically, a soft inorganic powder with a Mohs' hardness of about 3 to about 4.5 and a hard inorganic powder with a Mohs' hardness of about 5 to about 9 are desirably employed. The addition of a soft inorganic powder having a Mohs' hardness of about 3 to about 4.5 can stabilize the coefficient of friction with repeat running. At a hardness falling within the above range, the sliding guide rail is not worn down. The average particle diameter of the soft inorganic powder desirably falls within a range of about 30 nm to about 50 nm.

Examples of soft inorganic powders having a Mohs' hardness of about 3 to about 4.5 are calcium sulfate, calcium carbonate, calcium silicate, barium sulfate, magnesium carbonate, zinc carbonate, and zinc oxide. These may be employed singly or in combinations of two or more.

The content of the soft inorganic powder in the back layer desirably falls within a range of about 10 weight parts to about 140 weight parts, preferably about 35 weight parts to about 100 weight parts, per 100 weight parts of carbon black.

The addition of a hard inorganic powder having a Mohs' hardness of about 5 to about 9 can increase the strength of the back layer and enhance the running durability. When the hard inorganic powder is employed with carbon black and the above soft inorganic powder, a strong back layer undergoing little deterioration even with repeat sliding can be obtained. The addition of the hard inorganic powder can impart a suitable abrasive force, reducing adhesion of shavings to tape guide poles or the like. In particular, when a soft inorganic powder is employed together, sliding characteristics to the guide pole with rough surface can be improved and the coefficient of friction of the back layer can be stabilized.

The average particle size of the hard inorganic powder desirably falls within a range of about 80 nm to about 250 nm (preferably about 100 nm to about 210 nm).

Examples of hard inorganic powders having a Mohs' hardness of about 5 to about 9 are α-iron oxide, α-alumina, and chromium oxide (Cr₂O₃). These powders can be employed singly or in combination. Of these, α-iron oxide and α-alumina are desirable. The content of the hard inorganic powder is normally about 3 weight parts to about 30 weight parts, desirably about 3 weight parts to about 20 weight parts, per 100 weight parts of carbon black.

When employing the above soft inorganic powder and hard inorganic powder in combination in the back layer, the soft inorganic powder and hard inorganic powder are desirably selected for use so that the difference in hardness between the soft inorganic powder and hard inorganic powder is equal to or greater than about 2 (preferably equal to or greater than about 2.5, more preferably equal to or greater than about 3).

The above two different inorganic powders of different Mohs' hardnesses having the average particle sizes specified above and the above two types of carbon black of differing average particle size are desirably incorporated into the back layer.

A lubricant can be incorporated into the back layer. The lubricant can be suitably selected for use from among the lubricants given by way of example for use in the nonmagnetic layer or magnetic layer. Lubricant is normally added to the back layer in a range of about 1 weight parts to about 5 weight parts per 100 weight parts of binder.

### Protective Film and the Like

The formation of an extremely thin protective film on the magnetic layer can improve abrasive resistance. Coating a lubricant over the protective film to increase the sliding property can yield a magnetic recording medium of adequate reliability.

Examples of the material in the protective film are: silica, alumina, titania, zirconia, cobalt oxide, nickel oxide, and other oxides; titanium nitride, silicon nitride, boron nitride, and other nitrides; silicon carbide, chromium carbide, boron carbide, and other carbides; and graphite, amorphous carbon, and other forms of carbon. Generally, hard amorphous carbon known as “diamond-like carbon” is particularly desirable.

A protective film comprised of carbon is suitable as a protective film because it affords adequate abrasion resistance at extremely thin film thicknesses and tends not to stick to sliding components.

Examples of the method of forming a carbon protective film are as follows. For hard disks, sputtering is generally employed. For video tapes and other products that require continuous film formation, numerous methods employing plasma CVD, with its high film formation rate, have been proposed. Accordingly, these methods are desirably applied.

Among them, the plasma injection CVD (PI-CVD) method is reported to afford an extremely high film-forming rate, yield a hard protective carbon film, and yield a good protective film with few pinholes (for example: Japanese Unexamined Patent Publication (KOKAI) Showa Nos. 61-130487 and 63-279426, Japanese Unexamined Patent Publication (KOKAI) Heisei No. 3-113824, which are expressly incorporated herein by reference in their entirety, and the like).

The protective carbon layer desirably has a Vickers hardness of equal to or greater than about 1,000 kg/mm², preferably equal to or greater than about 2,000 kg/mm². The crystalline structure thereof is desirably amorphous and nonelectrically conductive.

When a diamond-like carbon film is employed as the protective carbon film, the structure can be confirmed by Raman spectral analysis. That is, the diamond-like carbon film can be measured for confirmation by the detection of a peak at 1520 to 1560 cm¹. When the structure of the carbon film shifts from a diamond-like structure, the peak detected by Raman spectral analysis will move out of this range and the hardness of the protective film will decrease.

Carbon-containing compounds such as alkanes such as methane, ethane, propane, and butane; alkenes such as ethylene and propylene; and alkynes such as acetylene can be employed as the carbon starting material in forming a protective carbon film. As needed, a carrier gas such as argon or an addition gas such as hydrogen or nitrogen to improve the film quality can be added.

When the protective carbon film is thick, electromagnetic characteristics may deteriorate and adhesion to the magnetic layer may decrease. When the film is thin, abrasion resistance may be inadequate. Accordingly, the film thickness is desirably about 2.5 nm to about 20 nm, preferably about 5 nm to about 10 nm.

To improve adhesion between the protective layer and substrate in the form of the magnetic layer, the surface of the magnetic layer can be etched in advance with an inert gas or exposed to a reactive gas plasma of oxygen or the like to modify the surface.

To improve running durability and corrosion resistance, a lubricant or rust-preventing agent is preferably incorporated into the magnetic layer or protective layer. The lubricant that is added can be in the form of a known hydrocarbon lubricant, fluorine lubricant, extreme pressure additive, or the like.

Examples of hydrocarbon lubricants are: carboxylic acids such as stearic acid and oleic acid; esters such as butyl stearate; sulfonic acids such as octadecyl sulfonic acid; phosphoric acid esters such as monooctadecyl phosphate; alcohols such as stearyl alcohol and oleyl alcohol; carboxylic acid amides such as stearic acid amide; and amines such as stearylamine.

Examples of fluorine lubricants are lubricants obtained by replacing all or part of the alkyl groups in the above hydrocarbon lubricants with fluoroalkyl groups or perfluoropolyether groups.

The perfluoropolyether groups are perfluoromethyleneoxide polymers, perfluoroethylenoxide polymers, perfluoro-n-propyleneoxide polymers (CF₂CF₂CF₂O)ₙ, perfluoroisopropyleneoxide polymers (CF(CF₃)CF₂O)ₙ, or copolymers thereof.

Compounds in the form of hydrocarbon lubricants having terminal alkyl groups or intramolecular polar functional groups such as hydroxyl groups, ester, groups, or carboxyl groups are highly effective at reducing abrasion and are suitable.

The molecular weight thereof can be about 500 to about 5,000, desirably about 1,000 to about 3,000. A molecular weight of about 500 to about 5,000 can inhibit volatization and a decreased lubricating property. It can also prevent high viscosity and prevent the slider from tending to adhere to the disk, resulting in stopped running, head crashing, and the like.

Specifically, the above perfluoropolyethers are commercially available as products such as FOMBLIN made by Audimond Co. and KRYTOX made by DuPont.

Examples of extreme pressure additives are phosphoric acid esters such as trilauryl phosphate; phosphorous acid esters such as trilauryl phosphite; thiophosphorous acid esters and thiophosphoric acid esters such as trilauryl trithiophosphite; and sulfur-based extreme pressure agents such as dibenzyldisulfide.

The above lubricants can be employed singly or in combinations of two or more. Methods of applying the lubricants on the magnetic layer or protective layer include the method of dissolving the lubricant in an organic solvent and applying it by wire bar, gravure, spin coating, dip coating, or the like, or adhering it by a vacuum vapor deposition method.

Examples of rust-preventing agents are: benzotriazole, benzoimidazole, purine, pyrimidine, and other nitrogen-containing heterocycles and derivatives thereof in which an alkyl side chain or the like has been incorporated onto a core nucleus thereof, and benzothiazole, 2-mercaptonebenzothiazole, tetrazaindene ring compounds, thiouracyl compounds, and other nitrogen and sulfur-containing heterocycles and their derivatives.

### Formation of Magnetic Layer and the Like

Details of the method of forming a magnetic layer comprising a magnetic material in which a soft magnetic material is exchange-coupled with a hard magnetic material are as set forth above. Additionally, when forming a nonmagnetic layer, the above-described nonmagnetic powder, binder, and the like can be mixed in a known solvent to prepare a nonmagnetic layer coating liquid. This coating liquid can then be used to form a nonmagnetic layer.

In the course of preparing a magnetic layer or nonmagnetic layer coating liquid, kneading processing can be conducted in an open kneader, continuous kneader, pressure kneader, extruder, or the like to dissolve the dispersion. Further, a dispersion medium such as glass beads, zirconia beads, titania beads, or steel beads can be employed to disperse the magnetic particles or nonmagnetic powder.

When the magnetic recording medium of the present invention comprises a multilayered structure with a nonmagnetic layer and a magnetic layer, it is desirably manufactured by a method such as the following.

The first method is that of first coating a nonmagnetic layer by a commonly employed gravure coating, roll coating, blade coating, or extrusion coating device, and then, while the nonmagnetic layer is still wet, coating a magnetic layer using the support pressurizing extrusion coating device disclosed in Japanese Examined Patent Publication (KOKOKU) Heisei No. 1-46186, Japanese Unexamined Patent Publication (KOKAI) Showa No. 60-238179, or Japanese Unexamined Patent Publication (KOKAI) Heisei No. 2-265672, which are expressly incorporated herein by reference in their entirety.

The second method is that of approximately simultaneously coating a nonmagnetic layer and a magnetic layer with a single coating head having two built-in coating liquid feeding slits, such as is disclosed in Japanese Unexamined Patent Publication (KOKAI) Showa No. 63-88080 and Japanese Unexamined Patent Publication (KOKAI) Heisei Nos. 2-17971 and 2-265672, which are expressly incorporated herein by reference in their entirety.

The third method is that of approximately simultaneously coating a nonmagnetic layer and a magnetic layer with the extrusion coating device equipped with backup rolls disclosed in Japanese Unexamined Patent Publication (KOKAI) Heisei No. 2-174965, which is expressly incorporated herein by reference in its entirety.

To prevent deterioration of the electromagnetic characteristics or the like of the magnetic recording medium due to aggregation of magnetic particles, it is desirable to apply shear to the coating liquid within the coating head by a method such as that disclosed in Japanese Unexamined Patent Publication (KOKAI) Showa No. 62-95174 or Japanese Unexamined Patent Publication (KOKAI) Heisei No. 1-236968, which are expressly incorporated herein by reference in their entirety. Further, it is desirable for the viscosity of the magnetic layer and nonmagnetic layer coating liquids to satisfy the numeric ranges disclosed in Japanese Unexamined Patent Publication (KOKAI) Heisei No. 3-8471, which is expressly incorporated herein by reference in its entirety. To achieve a multilayered structure, sequential multilayer coating can be conducted, in which, after coating and drying the nonmagnetic layer, the magnetic layer is provided thereover. However, it is desirable to employ the above simultaneous multilayer coating to reduce coating defects and improve quality with respect to dropout and the like.

In the case of a disk, adequately isotropic orientation can sometimes be achieved with no orientation without using an orienting device. However, the diagonal arrangement of cobalt magnets in alternating fashion or the use of a known random orienting device such as a solenoid to apply an a.c. magnetic field is desirable. In the case of a ferromagnetic metal powder, isotropic orientation is preferably vertical orientation when conducting particularly high-density recording. Spin coating can also be employed to effect circumferential orientation.

For a magnetic tape, longitudinal orientation can be conducted with cobalt magnets or solenoids. The drying position of the coating is desirably controlled by controlling the temperature and flow rate of drying air, and coating speed. A coating speed of about 20 m/min to about 1,000 m/min and a dry air temperature of equal to or higher than about 60° C. are desirable. Suitable predrying can be conducted prior to entry into the magnet zone.

As needed, calendering can be conducted on the magnetic recording medium after coating and drying described above. Calender rolls made of epoxy, polyimide, polyamide, polyamideimide, and other heat-resistant plastic rolls can be employed. Processing can also be conducted with metal rolls. When forming magnetic layers on both sides of the support, processing with metal rolls is preferred. The processing temperature is preferably equal to or higher than about 50° C., more preferably equal to or higher than about 100° C. The linear pressure is preferably equal to or higher than about 200 kg/cm (equal to or higher than about 196 kN/m), more preferably equal to or higher than about 300 kg/cm (equal to or higher than about 294 kN/m).

### Physical Characteristics

The magnetic recording medium of the present invention preferably has physical characteristics as described below.

The saturation magnetic flux density of the magnetic layer preferably ranges from about 0.1 T to about 0.3 T. The coercivity (Hc) of the magnetic layer is preferably about 159 kA/m to about 796 kA/m (about 2000 Oe to about 10000 Oe), more preferably about 159 kA/m to about 478 kA/m (about 2000 Oe to about 6000 Oe). Narrower coercivity distribution is preferable. The SFD is preferably equal to or lower than about 0.6.

For a magnetic disk, in the case of two-dimensional random, squareness is, for example, equal to or greater than about 0.55 and equal to or less than about 0.67, preferably equal to or greater than about 0.58 and equal to or less than about 0.64. In the case of three-dimensional random, squareness is, for example, equal to or greater than about 0.45 and equal to or less than about 0.55. When vertically oriented, squareness is, for example, equal to or greater than about 0.6, preferably equal to or greater than about 0.7 in the vertical direction. When demagnetizing field correction is conducted, squareness is, for example, equal to or greater than about 0.7, preferably equal to or greater than about 0.8. The orientation ratios of two-dimensional and three-dimensional random are both preferably equal to or greater than about 0.8. In the case of two-dimensional random, it is preferable for vertical squareness, Br, and Hc to all be within about 0.1-fold to about 0.5-fold their values in the in-plane direction.

In a magnetic tape, squareness is normally equal to or greater than about 0.55, preferably equal to or greater than about 0.7. The coefficient of friction of the magnetic recording medium of the present invention relative to the head is, for example, equal to or less than about 0.5 and preferably equal to or less than about 0.3 at temperatures ranging from −10° C. to 40° C. and humidity ranging from 0 percent to 95 percent, the surface resistivity on the magnetic surface preferably ranges from about 10⁴ ohm/sq to about 10¹² ohm/sq, and the charge potential preferably ranges from about −500 V to about +500 V. The modulus of elasticity at 0.5 percent extension of the magnetic layer preferably ranges from about 100 kg/mm² to about 2,000 kg/mm² (about 0.98 GPa to about 19.6 GPa) in each in-plane direction. The breaking strength preferably ranges from about 10 kg/mm² to about 70 kg/mm² (about 98 MPa to about 686 MPa). The modulus of elasticity of the magnetic recording medium preferably ranges from about 100 kg/mm² to about 1500 kg/mm² (about 0.98 GPa to about 14.7 GPa) in each in-plane direction. The residual elongation is preferably equal to or less than about 0.5 percent, and the thermal shrinkage rate at all temperatures below 100° C. is preferably equal to or less than about 1 percent, more preferably equal to or less than about 0.5 percent, and most preferably equal to or less than about 0.1 percent. The glass transition temperature (i.e., the temperature at which the loss elastic modulus of dynamic viscoelasticity peaks as measured at 110 Hz) of the magnetic layer preferably ranges from about 50° C. to about 120° C., and that of the lower nonmagnetic layer preferably ranges from about 0° C. to 100° C.

The loss elastic modulus preferably falls within a range of about 1×10⁹ μN/cm² to about 8×10¹⁰ μN/cm² and the loss tangent is preferably equal to or less than about 0.2. Adhesion failure tends to occur when the loss tangent becomes excessively large. These thermal characteristics and mechanical characteristics are desirably nearly identical, varying by equal to or less than about 10 percent, in each in-plane direction of the medium. The residual solvent contained in the magnetic layer is preferably equal to or less than about 100 mg/m² and more preferably equal to or less than about 10 mg/m². The void ratio in the coated layers, including both the nonmagnetic layer and the magnetic layer, is preferably equal to or less than about 30 volume percent, more preferably equal to or less than about 20 volume percent. Although a low void ratio is preferable for attaining high output, there are some cases in which it is better to ensure a certain level based on the object. For example, in many cases, larger void ratio permits preferred running durability in disk media in which repeat use is important.

The center surface average surface roughness Ra of the magnetic layer is preferably equal to or less than about 4.0 nm, more preferably equal to or less than about 3.8 nm, and still more preferably equal to or less than about 3.5 nm when measured for a surface area of 250 μm×250 μm with an optical interferotype surface roughness meter HD-2000 made by WYKO. The maximum height of the magnetic layer Rmax is preferably equal to or less than about 0.5 μm, the ten-point average surface roughness Rz is preferably equal to or less than about 0.3 μm, the center surface peak height Rp is preferably equal to or less than about 0.3 μm, the center surface valley depth Rv is preferably equal to or less than about 0.3 μm, the center-surface surface area percentage Sr is preferably equal to or greater than about 20 percent and equal to or less than about 80 percent, and the average wavelength Sλa is preferably equal to or greater than about 5 μm and equal to or less than about 300 μm. The surface properties of the magnetic layer can be readily controlled by controlling surface properties through the filler used in the support, by controlling the particle diameter and quantity of the powder added to the magnetic layer, and by controlling the roll surface configuration in calendar processing to optimize electromagnetic characteristics and the coefficient of friction. Curling is preferably controlled to within about ±3 mm.

### Method of Manufacturing Magnetic Recording Medium

The method of manufacturing magnetic recording medium of the present invention comprises:

(1) forming a hard magnetic layer by coating a coating liquid comprising a hard magnetic material comprising a rare earth element on a nonmagnetic organic material support, and

(2) forming, on at least a portion of a surface of the hard magnetic material comprised in the hard magnetic layer, a soft magnetic region, the soft magnetic region being exchange-coupled with the hard magnetic material.

As set forth above, the sputtering temperature is quite high in vapor phase synthesis of a hard magnetic material because it is necessary to induce rearrangement of the atoms. By contrast, the low sputtering temperature of soft magnetic materials makes it possible to sputter them onto even organic material supports. Accordingly, a hard magnetic material is not synthesized on an organic material support in the method of manufacturing a magnetic recording medium of the present invention; instead, a presynthesized hard magnetic material is coated to form a hard magnetic layer, after which a soft magnetic material is sputtered thereover to form a soft magnetic region exchange-coupled with the hard magnetic material over at least a portion of the surface of the hard magnetic material contained in the hard magnetic layer. It is thus possible to form a magnetic layer comprising a magnetic material achieving both thermal stability and recording properties on a nonmagnetic organic material support. The details of the method of manufacturing a magnetic recording medium of the present invention are as set forth above.

### EXAMPLES

The present invention will be described in detail below based on Examples and Comparative Examples. However, the present invention is not limited to the following Examples.

### 1. Fabrication of Hard Magnetic Material

(Preparation of Thin Quenched Band)

The following operation was conducted in an Ar atmosphere.

A Nd₂Fe₁₄B alloy with Nd as starting material was melted in an arc furnace and cooled to produce a base alloy comprising 18 atomic percent Nd.

The base alloy was charged to a quartz tube the front end of which had been processed into an orifice, the alloy was melted at high frequency, pressure was applied with Ar, and the molten metal was passed through the orifice and blown onto rotating copper rolls to fabricate a thin quenched band. The rotational speed of the rolls at the time was 20 m/s.

The amorphous thin quenched band was heated in a 500° C. nitrogen atmosphere until the particle diameter reached 10 nm. The formation of Nd₂Fe₁₄B crystals was confirmed by X-ray diffraction. After unidirectional polarization at 5,572 kA/m (70 kOe), the coercivity was 955 kA/m (1,2000 Oe) as measured under an applied magnetic field of 1,274 kA/m (16 kOe) with a vibrating sample magnetometer (VSM) made by Toei Industry Co., Ltd.

(Recovering Single Crystal Nanocrystals of Rare Earth—Transition Metal—Metalloid from Thin Quenched Band)

The thin quenched band was immersed in a 0.1 kmol/m³ aqueous solution of NaCl prepared with distilled water that had been deoxygenated by bubbling N₂ gas to dissolve away the Nd-rich phase of the crystal grain boundaries to recover Nd₂Fe₁₄B crystals. Subsequently, the crystals were washed with deoxygenated distilled water to remove the NaCl. The coercivity, as measured by the above method, was 637 kA/m (8,000 Oe) and the average particle size was 20 nm.

### 2. Fabrication of Magnetic Recording Medium

Four weight parts of the hard magnetic material Nd₂Fe₁₄B particles obtained by the above process were dispersed with 0.1 weight part of oleic acid and 0.1 weight part of oleylamine as dispersing adjuvants in 5 mL of decane to prepare a coating liquid for forming a hard magnetic layer.

Subsequently, a spin coater was employed to coat and dry the coating liquid on a PET film and form a hard magnetic layer 25 nm in thickness.

In Examples 1 to 8, the above-described hard magnetic layer surface was ion etched with a sputtering device (product name SC-701, made by Sanyu Electronics). Subsequently, the soft magnetic materials indicated in Table 1 were sputtered. Sputtering was conducted at a sputtering substrate temperature of 40° C., and the sputtering thickness was selected based on conditions preset into the device.

### 3. Evaluation of Magnetic Material in the Magnetic Layer

(1) Coercivity measurement

The coercivity of the magnetic material contained in the magnetic layer formed by the above-described method was measured under an applied magnetic field of 3,191 kA/m (40 kOe) with a superconducting vibrating sample magnetometer (VSM) made by Tamakawa Co., Ltd.

(2) Measure of the Aspect Ratio

Five hundred particles were randomly extracted from a photograph of the magnetic layer formed by the above method taken by a transmission electron microscope, and the average value of the aspect ratios that were measured is given in Table 1.

TABLE 1

| | Type of | | | |
|---|---|---|---|---|
| | soft | Sputtering | | |
| | magnetic | thickness | Aspect | |
| | material | (nm) | ratio | Coercivity |
| Ex. 1 | Fe | 2 | 1.2 | 438 kA/m (5500 Oe) |
| Ex. 2 | Fe | 5 | 1.5 | 398 kA/m (5000 Oe) |
| Ex. 3 | Fe | 8 | 1.8 | 478 kA/m (6000 Oe) |
| Ex. 4 | Fe | 10 | 2 | 494 kA/m (6200 Oe) |
| Ex. 5 | Permalloy | 2 | 1.2 | 478 kA/m (6000 Oe) |
| Ex. 6 | Permalloy | 5 | 1.5 | 438 kA/m (5500 Oe) |
| Ex. 7 | Permalloy | 8 | 1.8 | 517 kA/m (6500 Oe) |
| Ex. 8 | Permalloy | 10 | 2 | 533 kA/m (6700 Oe) |
| Comp. Ex. 1 | None | — | 1 | 637 kA/m (8000 Oe) |

### 4. Measurement of the Coercivity of the Soft Magnetic Material

Fe: The coercivity of the film obtained by sputtering under the same conditions as during sample preparation in Example 4 was measured with an external magnetic field of 10 KOe with a VSM made by Toei Industry Co., Ltd. at 2 kA/m (26 Oe).

Permalloy: The coercivity of the film obtained by sputtering under the same conditions as during sample preparation in Example 8 was measured with an external magnetic field of 10 KOe with a VSM made by Toei Industry Co., Ltd. at 4 kA/m (56 Oe).

### Evaluation Results

The coercivities of the magnetic materials contained in the magnetic layers of Examples 1 to 8 were lower than those prior to sputtering of the soft magnetic materials. Thus, the sputtering was confirmed to have formed a soft magnetic region exchange-coupled with the hard magnetic material on the surface of the hard magnetic material. Due to the high crystal magnetic anisotropy of the hard magnetic material, despite good thermal stability, the external magnetic field required for recording was large due to high coercivity, and thus recording was difficult. By contrast, by exchange coupling the soft magnetic material with the hard magnetic material as set forth above in the present invention, the recording properties of the hard magnetic material, with its good thermal stability, were improved.

The present invention permits the inexpensive manufacturing of a magnetic recording medium having both thermal stability and recording properties. The magnetic recording medium of the present invention is suited to general-purpose magnetic recording media such as a videotapes, computer tapes, and flexible disks.

Although the present invention has been described in considerable detail with regard to certain versions thereof, other versions are possible, and alterations, permutations and equivalents of the version shown will become apparent to those skilled in the art upon a reading of the specification and study of the drawings. Also, the various features of the versions herein can be combined in various ways to provide additional versions of the present invention. Furthermore, certain terminology has been used for the purposes of descriptive clarity, and not to limit the present invention. Therefore, any appended claims should not be limited to the description of the preferred versions contained herein and should include all such alterations, permutations, and equivalents as fall within the true spirit and scope of the present invention.

Having now fully described this invention, it will be understood to those of ordinary skill in the art that the methods of the present invention can be carried out with a wide and equivalent range of conditions, formulations, and other parameters without departing from the scope of the invention or any embodiments thereof.

All patents and publications cited herein are hereby fully incorporated by reference in their entirety. The citation of any publication is for its disclosure prior to the filing date and should not be construed as an admission that such publication is prior art or that the present invention is not entitled to antedate such publication by virtue of prior invention.

What is claimed is:

1. A magnetic recording medium comprising a magnetic layer on a nonmagnetic organic material support, wherein
the magnetic layer comprises a magnetic material comprising a hard magnetic material comprising a rare earth element, and on a portion of a surface of the hard magnetic material, a soft magnetic region, and
the soft magnetic region is exchange-coupled with the hard magnetic material.

2. The magnetic recording medium according to claim 1, wherein the magnetic material has an aspect ratio ranging from about 1.4 to about 5.

3. The magnetic recording medium according to claim 1, wherein the magnetic material has an aspect ratio ranging from about 1.4 to about 3.

4. The magnetic recording medium according to claim 1, wherein the magnetic material has an aspect ratio ranging from about 1.2 to about 2

5. The magnetic recording medium according to claim 1, wherein the hard magnetic material is comprised of a rare earth element, transition metal element, and boron.

6. A method of manufacturing a magnetic recording medium comprising:
forming a hard magnetic layer by coating a coating liquid comprising a hard magnetic material comprising a rare earth element on a nonmagnetic organic material support, and
forming, on at least a portion of a surface of the hard magnetic material comprised in the hard magnetic layer, a soft magnetic region, the soft magnetic region being exchange-coupled with the hard magnetic material.

7. The method of manufacturing a magnetic recording medium according to claim 6, wherein the formation of the soft magnetic region is conducted by sputtering a soft magnetic material on the hard magnetic layer.

8. The method of manufacturing a magnetic recording medium according to claim 6, wherein the hard magnetic material is comprised of a rare earth element, transition metal element, and boron.
